(19) United States
(12) Patent Application Publication
(10) Pub. No.: US 2015/0003637 A1
(43) Pub. Date: Jan. 1, 2015

(54) METHOD FOR UTILIZING MULTI-TONE IDENTIFICATION AND AUDIO APPARATUS UTILIZING THE SAME

(71) Applicant: Fortemedia, Inc., Sunnyvale, CA (US)

(72) Inventors: Shomo Chen, San Jose, CA (US); Ion Elinor Opris, San Jose, CA (US); Lan Lee, Palo Alto, CA (US)

(21) Appl. No.: 13/932,144

(22) Filed: Jul. 1, 2013

(51) Int. Cl. H03G 5/00

(52) U.S. Cl. CPC H03G 5/00
USPC 381/122

(57) ABSTRACT

A method for utilizing multi-tone identification and an audio apparatus utilizing the same are provided. The audio apparatus includes a microphone, a tone generator, a modulator and an amplifier. The microphone is configured to generate an audio signal. The tone generator is configured to generate a set of tones which represents a level of service, wherein the level of service indicates a service provided to the audio signal. The modulator, coupled to the microphone and the tone generator, is configured to modulate the audio signal with the set of tone to generate a modulated signal. The amplifier, coupled to the modulator, is configured to amplifying the modulated signal.

### BACKGROUND OF THE INVENTION

1. Field of the Invention

The present invention relates to a microphone system, and in particular, to a method for utilizing multi-tone identification and an audio apparatus utilizing the same in the microphone system.

2. Description of the Related Art

An audio system contains one or more microphones which extract a voice input from ambient environment, suppress noise, and produce high fidelity recordings.

Often, different audio services are demanded by different manufacturers and users to suit their own special requirements.

Traditionally in an audio system such as a voice recorder, the audio data is amplified, filtered and send to the next stage for further processing. The next stage processing unit has no information about the manufacturer of the audio device or the level of service that should be applied to the audio data. Therefore the same set of service procedures are provided to all users. The conventional audio device offers no controllability over the services provided to different manufacturers and users.

### BRIEF SUMMARY OF THE INVENTION

A detailed description is given in the following embodiments with reference to the accompanying drawings.

An embodiment of a method is provided, by an audio apparatus, comprising: generating an audio signal; generating a set of tones which represents a level of service; modulating the audio signal with the set of tone to generate a modulated signal; amplifying the modulated signal; wherein the level of service indicates a service provided to the audio signal.

Another embodiment of an audio apparatus is disclosed, comprising a microphone, a tone generator, a modulator and an amplifier. The microphone is configured to generate an audio signal. The tone generator is configured to generate a set of tones which represents a level of service, wherein the level of service indicates a service provided to the audio signal. The modulator, coupled to the microphone and the tone generator, is configured to modulate the audio signal with the set of tone to generate a modulated signal. The amplifier, coupled to the modulator, is configured to amplifying the modulated signal.

### BRIEF DESCRIPTION OF THE DRAWINGS

The present invention can be more fully understood by reading the subsequent detailed description and examples with references made to the accompanying drawings, wherein:

FIG. 1 is a block diagram of an audio apparatus 1 according to an embodiment of the invention;

FIG. 2 is a block diagram of the microphone device 100 according to an embodiment of the invention;

FIG. 3 is a block diagram of the tone modulator 102 according to an embodiment of the invention;

FIG. 4 is a block diagram of the tone generator 106 according to an embodiment of the invention;

FIG. 5 is a block diagram of the amplifier and ADC 104 according to an embodiment of the invention;

FIG. 6 is a block diagram of the FFT circuit 108 according to an embodiment of the invention;

FIG. 7 is a block diagram of the tone identification circuit 110 according to an embodiment of the invention;

FIG. 8 is a block diagram of the data processor 112 according to an embodiment of the invention; and

FIG. 9 is a flowchart of a signal processing method 8 according to an embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

It should be noted that the microphone system described herein may reside in a voice recorder, a mobile phone, a computer, a tablet, an audio apparatus, or any computing, communication, or consumer electronic device.

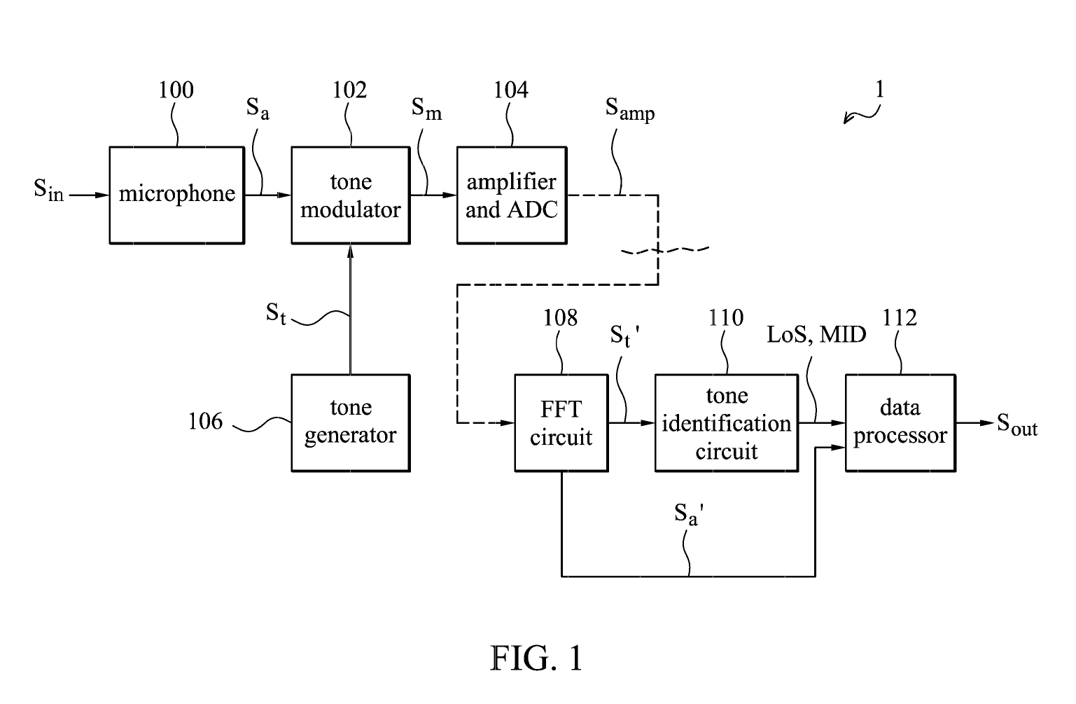

FIG. 1 is a block diagram of a microphone system 1 according to an embodiment of the invention, including a microphone 100, a tone modulator 102, an amplifier and analog-to-digital converter (ADC) 104, a tone generator 106, a Fast Fourier Transform (FFT) circuit 108, a tone identification circuit 110, a data processor 112. The microphone 100, the tone modulator 102, the amplifier and ADC 104 and the tone generator 106 may be integrated together as a microchip.

The FFT circuit 108, the tone identification circuit 110 and the data processor 112 may be implemented in software or hardware, integrated along with or separately from the microphone 100, the modulator 102, the amplifier and ADC104 and the tone generator 106 into a microchip. In some embodiments, the microphone 100, the tone modulator 102, the amplifier and ADC104 and the tone generator 106 may be integrated into a microphone client device and the tone identification circuit 110 and the data processor 112 may be integrated into a microphone server device. The microphone server device may receive audio signals from a plurality of microphone client devices, and provide specific services to the audio signals depending on the purchased service level of each microphone client device. In other embodiments, all components in FIG. 1 are integrated into one microphone device. Each microphone device produces an audio signal which carries the service level information. The audio signal is later decoded and processed according to the assigned service level.

The microphone system 1 can offer different levels of service to different users or different manufacturer of the microphone client device. For examples, a user A may purchase a basic level of service on the microphone system 1 which simply records what's received by the microphone 100, another user B may purchase a higher level of service on the microphone system 1 which identifies the direction of the voice source and process the audio signal Sₐ by removing the noises from other directions and leaving the voice in the identified direction, yet another user C may purchase a another level of service on the microphone system 1 which provides phase matching to a plurality of received audio signals Sₐ. The services offered by the microphone system 1 may be implemented in software, hardware, or a combination thereof. The microphone system 1 can find applications in audio microchip identification and software identification including audio data processing, where amplitudes and phases of multiple signals are required to be matched, noise level is required to be suppressed and filtered.

The microphone system 1 can identify different levels of service by firstly modulating the information of a user identifier or manufacturer identifier MID and a level of service indicator LoS into the audio signal Sₐ generated by the microphone 100. Later, the microphone system 1 can recover the information about the manufacturer identifier MID and the level of service indicator LoS, and provide an appropriate level of the level of service to the audio signal Sₐ based on the recovered information, thereby offering different levels of service to different users.

The microphone 100 is an acoustic to electric converter which transforms an acoustic pressure to an electrical signal Sₐ for recording, hearing or further data processing. The tone generator 106 generates a set of tone Sₜ which includes single or multiple tones signal. The set of tone Sₜ represents the manufacturer identifier MID and/or the level of service indicator LoS specific to the user, or to the device which includes the microphone 100, the tone modulator 102, the amplifier and ADC 104 and the tone generator 106. The tone modulator 102 is a mixer circuit which modulates the audio signal Sₐ and the set of tones Sₜ to create a modulated signal Sₘ containing the information of the audio source Sₐ as well as the manufacturer identifier MID and the level of service LoS. The amplifier and ADC 104 is the amplification data processing circuit which amplifies the analog signal Sₘ from unit 102, filters and converts the amplified output Sₐₘₚ into a digital form.

The FFT circuit 108 is Fast Fourier Transform circuit which converts the received signal Sₐₘₚ from the time to frequency domain and extracts frequency components from the frequency domain signal for further processing. In particularly, the FFT circuit 108 can separate the set of tones Sₜ′ and the audio signal Sₐ′ in the frequency domain signal. The tone identification circuit 110 computes and decodes the manufacturer identifier MID and the level of service LoS according to the set of tones Sₜ′ for determining the levels of service for the extracted audio signal Sₐ′. The data processor 112 may be one or more controllers, microcontrollers, microprocessors, or processors which either employ a circuit block or load associated software codes to provide the appropriate service(s) to present data Sₐ′ based on the decoded parameters MID and LoS, outputting a processed signal Sₒᵤₜ for recording, playing or other purposes.

In some embodiments, the set of tones represent only the level of service LoS, the data processor 112 can perform the services for the extracted audio signal Sₐ′ based on the level of service LoS. In other embodiments, the set of tones represent only the manufacturer identifier MID, the data processor 112 can contain a list of eligible manufacturers and the level of service thereof, determine the level of service according to the manufacturer identifier MID, and perform the services for the extracted audio signal Sₐ′ based on the determined level of service. In yet other embodiments, the set of tones represent a combination of the manufacturer identifier MID and the level of service LoS, the data processor 112 can search from a list of eligible manufacturers for the manufacturer identifier MID, and when a matched manufacturer is found, perform the services for the extracted audio signal Sₐ′ based on the level of service LoS.

The microphone system 1 is configured to provide appropriate level of the service to each user by including the information of the manufacturer identifier and the level of service indicator into the audio signal, enhancing service management to the audio device.

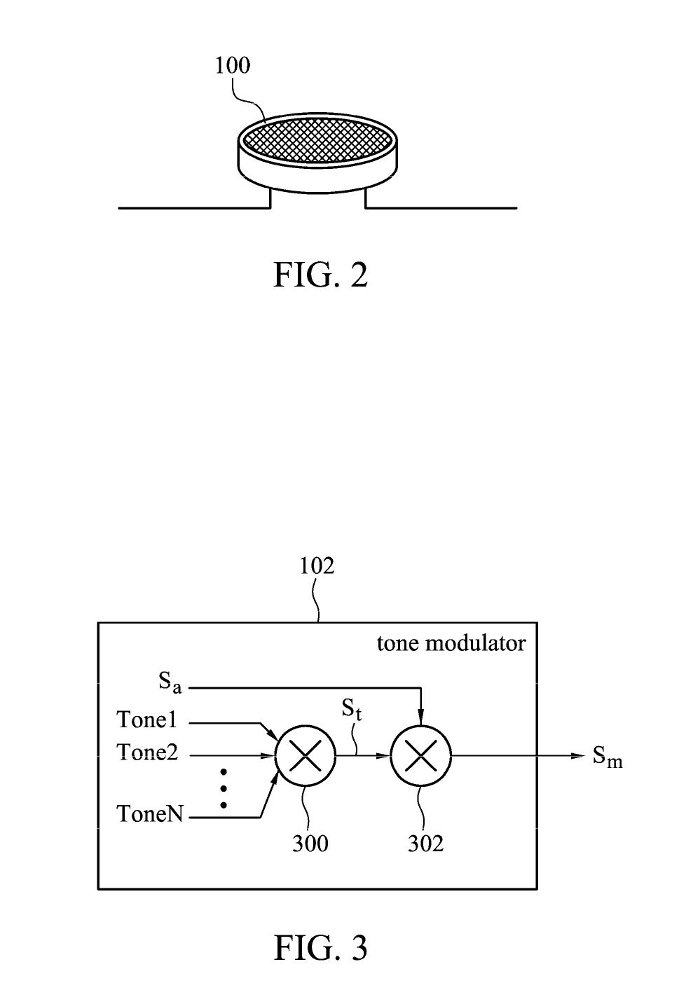

FIG. 2 is a block diagram of the microphone device 100 according to an embodiment of the invention. The microphone 100 may be a digital capacitor microphone, a digital MicroElectrical-mechanical System (MEMS) microphone, a condenser microphone, or a set of array microphones, containing an acoustic transducer or an analog sensor which converts air pressure into the analog electrical signal Sₐ and offering the advantage of increased immunity of electrical noise pickup. The air pressure may be caused by a speaker giving a speech or a conversion near the microphone device 100. The microphone 100 transforms the voice in the air into the audio signal Sₐ and subsequently passes the audio signal to the tone modulator 102.

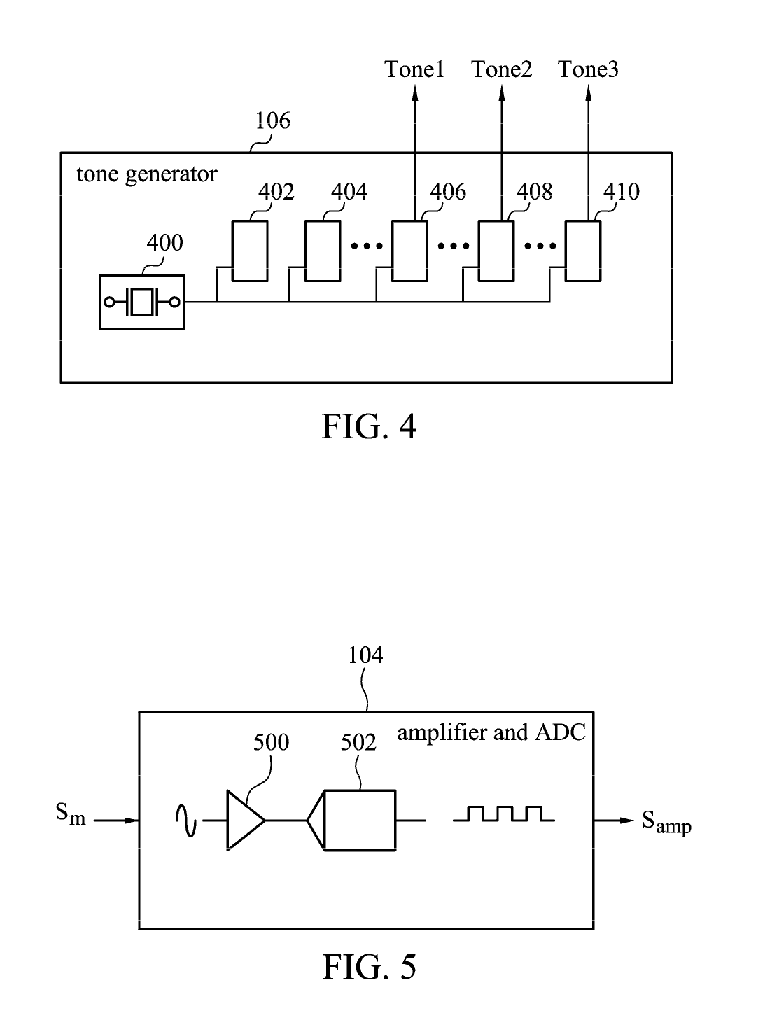

FIG. 4 is a block diagram of the tone generator 106 according to an embodiment of the invention, including an oscillation source 400 and a frequency divider containing circuit components 402 through 410. The tone generator 106 generates and sends the set of tones Sₜ which include output tones Tone1, Tone2 and Tone3 to the tone modulator 102, representing the user identifier or manufacturer identifier MID and the level of service indicator LoS.

The oscillation source 400 may be an external sinusoidal input signal source, a digital clock signal source, a crystal oscillator, or a resistor and capacitor oscillator.

The frequency divider can be implemented using flip flop or resistor-and-capacitor circuitry. Due to limited audio frequency bands, noise level, frequency mismatch, signal amplitude, number of tones to be added to the input signal and distance between the tones, the output tones Tone1, Tone2 and Tone3 and ratio of output tones need to be substantially fixed in order for the tone identification circuit 110 in FIG. 1 to decode the manufacturer tones correctly.

One way of implementing the fixed frequency tones and fixed tone ratio is to employ a crystal oscillator unit as the oscillation source 400 for the frequency source and utilize the same sizes of resistors, capacitors, or transistors for the circuit components 402 through 410 in the divider circuit for providing the divided frequency ratio. The circuit components 402 through 410 in the frequency divider are substantially identical digital flip flops including substantially identical resistors, capacitors and/or transistors, outputting the tones Tone1, Tone2 and Tone3 with a tone ratio matching. The output tone levels of the output tones Tone1, Tone2 and Tone3 must be set properly to not interfere with the audio source signal Sₐ from microphone 100, that is, being inaudible to the human hearing range. For example, the magnitudes of the tones Tone1, Tone2 and Tone3 may be configured to be less than the audio signal Sₐ, or located outside the range of the audio signal Sₐ.

The set of tones generated by 106 are used to identify the manufacturer and the level of service to be provided to the audio signal Sₐ. Amplitudes of output tones Tone1, Tone2, and ToneN may be set equally to one another or as multiples of one another, and at 50 dB or a proper level below the peak amplitude of the audio signal Sₐ, thus the output tones Tone1, Tone2, and ToneN will not hamper the audio signal Sₐ.

In some implementations, the set of tones are encoded by an amplitude ratio of the output tones. In some embodiments, the amplitudes of the output tones Tone1, Tone2, ToneN are produced by the circuit components 402 through 410 in a predefined ratio of 2 for any two adjacent tones. For example, the amplitudes of the output tones Tone1, Tone2, ToneN are −50 dB, −53 dB, −56 dB respectively, hence the data processor 112 can decode the set of tones based on the predefined amplitude ratio and identify a corresponding user/manufacturer and level of service.

In other implementations, the set of tones are encoded by a frequency ratio of the output tones. For example, the frequencies of the output tones Tone1, Tone2, ToneN may be produced at 5 KHz, 6 KHz and 7.2 KHz by the circuit components 402 through 410, with a ratio of 1.2 for ToneN to Tone2 and Tone2 to Tone1. In the example, a particular set of the frequency positions and frequency ratios combination represent the manufacturer is a user or company XYZ-1 and the level of service is 3 on the scale of 1 to 4, with 4 being the highest level of service. In another example, the frequencies of the output tones Tone1, Tone2, ToneN may be set as 5 KHz, 10 KHz and 24 KHz and the frequency ratios of ToneN to Tone2 and Tone2 to Tone1 may be respectively set as 2.4 and 2, therefore the data processor 112 can use the information of the set of tones to identify another user/manufacturer and another service level.

In some other implementations, the amplitude and frequency ratio produced by the tone generator 106 are dynamically adaptable or programmable to accommodate the level of service required for present audio data Sₐ. The set of tones may be sent periodically, in a predictable period, a programmable period or only in a certain time domain such as a power-on or an idle period when no audio data is being generated and processed.

Although 3 output tones Tone1, Tone2, ToneN are utilized for the set of tones, those skilled in the art will recognize that other number of tones may be employed to show a combination of the manufacturer and the level of service.

The tone generator 106 can generate a set of tones which represents a combination of the manufacturer and the level of service, allowing the microphone system to provide a service to each user according to the manufacturer and the level of service.

FIG. 3 is a block diagram of the tone modulator 102 according to an embodiment of the invention, including a first mixer 300 and a second mixer 302. The tone modulator 102 is configured to mix the audio signal Sₐ and the set of tones Sₜ together to generate a modulated signal Sₘ which carrying the information of both the audio signal Sₐ and the set of tones Sₜ.

The tone modulator 102 is a frequency mixer block which receives the audio signal Sₐ from the microphone 100 and the set of tones Sₜ from the tone generator 106 to produce the modulated signal Sₘ. The modulated signal Sₘ contains sum and difference frequency components of the audio signal Sₐ and the set of tones Sₜ. The mixer circuits 300 and 302 can be implemented by a diode mixer, bipolar mixer, FET (field effect transistor) mixer or any mixer circuitry which can provide the intended combination of signals. The first mixer 300 may be implemented by a double balanced mixer to equally suppress all components in the set of tones Sₜ or attenuate the components of the set of tones Sₜ based on the intended amplitude ratio. The second mixer 302 may be implemented by a single balanced mixer, thus only the output signal Sₘ is adjusted to an appropriate level but not the audio signal Sₐ from the microphone 100. For example, the amplitudes of the output tones Tone1, Tone2, and ToneN after being mixed with the audio signal Sₐ may have amplitude ratios of 2.4 and 2 for the mixed ToneN to mixed Tone2 and mixed Tone2 to mixed Tone1 respectively, representing a user XYZ-2 and a level of service could be 4 with 4 being the highest level of service.

The tone modulator 102 mixes the audio signal Sₐ with the set of tones Sₜ which represents the manufacturer and the level of service, controls amplitude of each tone, and delivers the resultant modulated signal Sₘ to the amplifier and ADC 104.

FIG. 5 is a block diagram of the amplifier and ADC 104 according to an embodiment of the invention, including an amplifier 500 which amplifies the received signal Sₘ and an ADC 502 which converts the signal into the digital form. The amplifier and ADC 104 receives the modulated signal Sₘ from the tone modulator, filters, amplifies and digitizes the received modulated signal Sₘ to produce the amplified signal Sₐₘₚ.

The ADC 502 may be implemented in the FFT circuit 108 rather than the circuit 104. The amplifier 500 may be implemented by bipolar transistors, FET transistors, a single ended amplifier, a differential amplifier, a switched mode amplifier or any amplifier circuitry which provides the intended gain. The ADC 502 may be implemented by a flash ADC, a sigma delta ADC, or any analog to digital converter that provides a required input signal to the FFT circuit 108 for fast Fourier transform (FFT) computation.

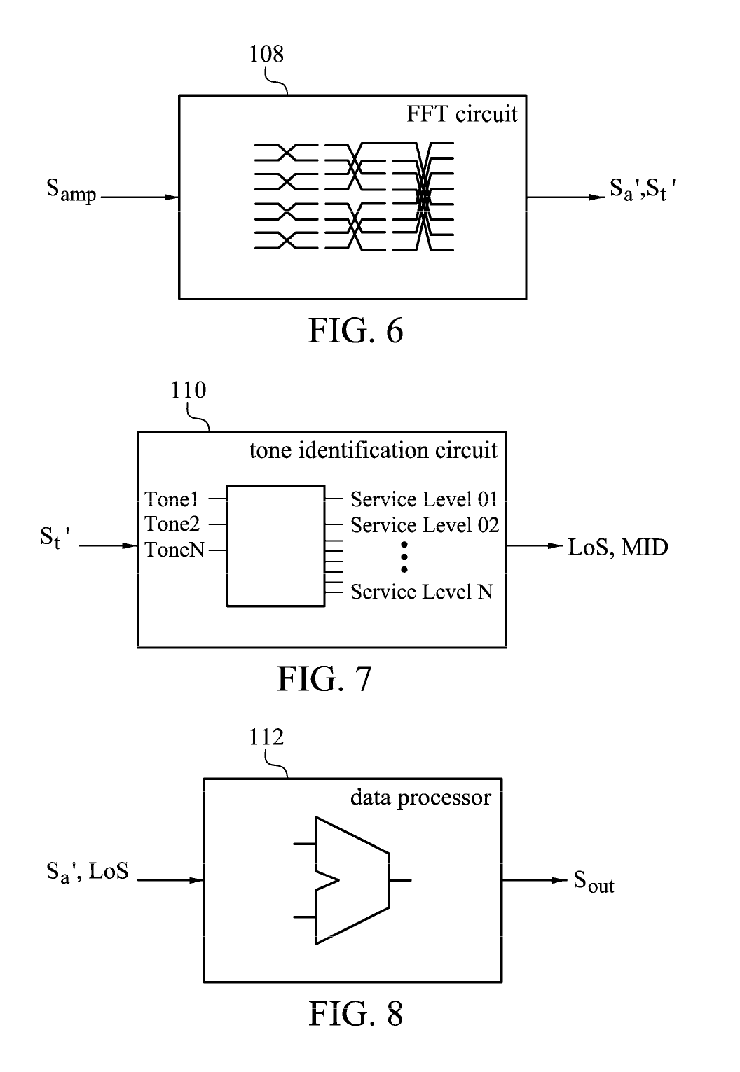

FIG. 6 is a block diagram of the FFT circuit 108 according to an embodiment of the invention.

The FFT circuit 108 is configured to recover the set of tone Sₜ′ and the audio signal Sₐ′ from the amplified signal Sₐₘₚ, and respectively direct the set of tone Sₜ′ to the tone identification circuit 110 and the audio signal Sₐ′ to the data processor 112. The FFT circuit 108 transforms the amplified signal Sₐₘₚ to the frequency domain and decodes all the periodic signal components or tones as the set of tones Sₜ′ with the corrected number of frequency tones, tone positions, frequency ratio, and amplitude ratio. After extracting the set of tones Sₜ′ from the frequency domain signal, the FFT circuit 108 can transmit the remaining signal as the extracted audio signal Sₐ′ to the data processor for the next stage process.

After the separation of each audio frequency component, the source audio signal, Tone1, Tone2 and ToneN can be identified for the manufacturer identifier MID and/or the level of service LoS. The FFT operation may be implemented by Cooley Tukey algorithm, Rader's algorithm or any FFT algorithm that best suits for the hardware or software implementation.

FIG. 7 is a block diagram of the tone identification circuit 110 according to an embodiment of the invention.

The tone identification circuit 110 is decoding block which decodes the manufacturer identifier MID and the level of service LoS from the set of tones Sₜ′ based on the number of the frequency tones, the tone positions, the amplitude ratio and frequency ratio. The tone identification circuit 110 may contain a preprogrammed tone table for mapping the manufacturer identifier MID and/or the level of service LoS. The audio service provider can select a setting from the preprogrammed tone table to indicate manufacturer identifier MID and/or assign the level of service LoS.

The tone table could also be implemented as a dynamic changeable tone table, where the level of service can be changed and updated by the audio service provider. A combination of the number of frequency tones, tone positions, frequency ratio and amplitude ratio are programmed on-the-fly by the audio service provider to correspond to the manufacturer identifier MID and/or the level of service LoS. The audio service provider may change the multi-tone representation for the manufacturer identifier MID and/or the level of service LoS through a software interface installed on the data processor 112. For example, for the audio client-server configuration, the audio service provider may configure the number of frequency tones, tone positions, frequency ratio and amplitude ratio, and the corresponding level of service LoS for the received audio data Sa′ by the software interface, during providing the audio services to the users of the audio client devices.

FIG. 8 is a block diagram of the data processor 112 according to an embodiment of the invention.

Based on the manufacturer identifier MID and the level of service LoS, The data processor 112 provides various levels of service, such as audio phase correction, amplitude correction, arithmetic calculation, noise suppression, different frequency bands filtering or simply passes the present data without any processing.

The level of service parameter LoS is utilized to select one or more signal processing provided by the data processor 112. The data processor 112 can perform a service of the selected signal processing to the extracted audio signal Sₐ′ according to the manufacturer identifier MID and the level of service LoS. In some embodiments, the data processor 112 can compare the manufacturer identifier MID to a list of eligible manufacturers, and perform the services indicated by the level of service LoS for the audio data Sₐ′ to produce the output signal Sₒᵤₜ only when the manufacturer identifier MID matches to a candidate in the eligible manufacturer list.

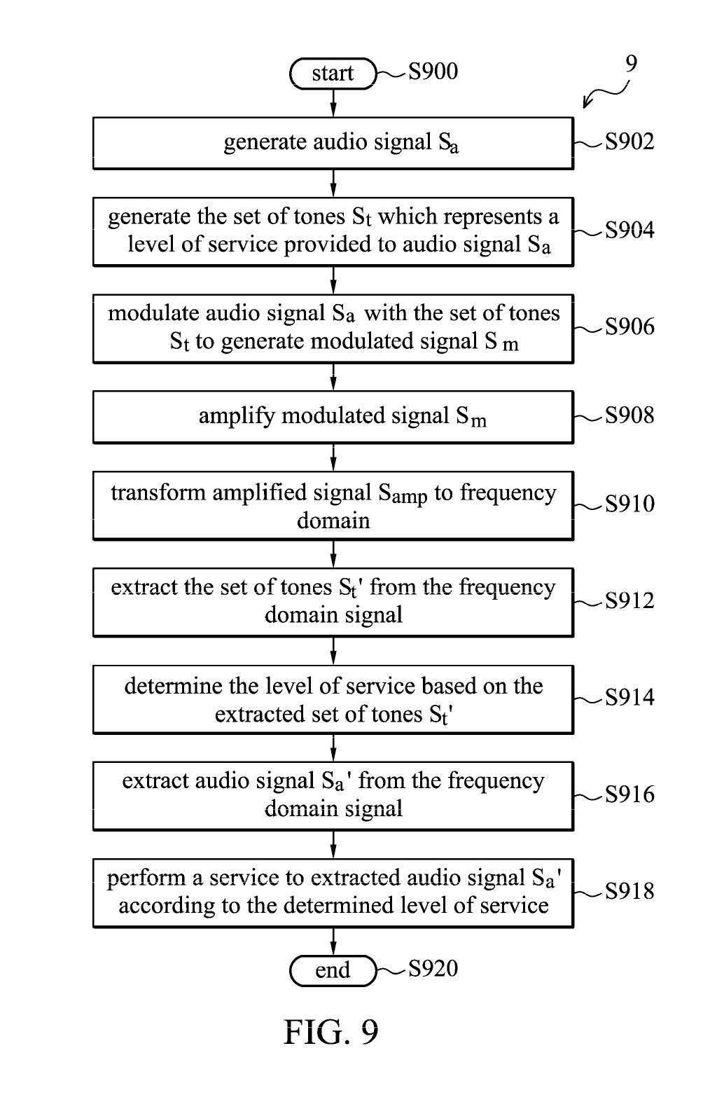

FIG. 9 is a flowchart of a signal processing method 9 according to an embodiment of the invention, incorporating the microphone system 1 in FIG. 1.

Upon startup, the microphone system is powered on, and the microphone 100 detects the voice in the air to produce the electrical audio signal Sₐ (S902). Concurrently, the tone generator 106 generates the set of tones Sₜ which represents the level of service to be provided to the audio signal Sₐ (S904). The set of tones Sₜ may be encoded by the number of frequency tones, tone positions, frequency ratio and amplitude ratio to represent the level of service for the audio signal. In some embodiments, a fixed combination of the number of frequency tones, tone positions, frequency ratio and amplitude ratio are used to represent the level of service. In other embodiments, the combination of the number of frequency tones, tone positions, frequency ratio and amplitude ratio is programmable, adaptable by the audio service provider. The audio service provider can configure the number of frequency tones, tone positions, frequency ratio and amplitude ratio and its corresponding level of service through a hardware or software interface on the microphone system 1. For example, the audio service provider may dynamically configure 3 frequency tones respectively at 5 k, 10 k, 24 k, each with the same amplitude to represent the service level of 3, indicating that the phase matching, amplitude matching, arithmetic calculation, noise suppression are applied to the detected audio signal Sₐ′. The dynamical configuration may be input by a software interface. Upon receiving the configuration change, the audio system 1 will update the tone table in the tone identification circuit 110 and the circuit configuration in the tone generator 106 according to the new configuration, so that the level of service may be encoded and decoded accurately.

The tone modulator 102 mixes the audio signal Sₐ and the set of tones Sₜ together to generate the modulated signal Sₘ (S906), which is then amplified, digitized, and filtered by the amplifier and ADC 104 to provide the filtered signal Sₐₘₚ.

The microphone client device may next transmit the filtered signal Sₐₘₚ to the microphone server device, where the FFT circuit 108 can receive and transform the filtered signal Sₐₘₚ from the time to frequency domain, and subsequently, the FFT circuit 108 can further extract the set of tones Sₜ′ (S912) and the audio signal Sₐ′ (S916) from the frequency domain signal and respectively deliver the extracted set of tones Sₜ′ to the tone identification circuit 110 and the extracted audio signal Sₐ′ to the data processor 112.

The tone identification circuit 110 can determine the level of service based on the extracted set of tones Sₜ′ (S914). For example, the tone identification circuit 110 may contain the tone table which includes information on the number of frequency tones, the tone positions, the frequency ratio and the amplitude ratio, and the corresponding manufacturer identifier MID and level of service LoS. The tone identification circuit 110 can search the tone table for the extracted set of tones Sₜ′ which matches the number of frequency tones, tone positions, frequency ratio and amplitude ratio, thereby determining the level of service to be provided to the audio signal Sₐ′.

In Step S916, the data processor 112 can perform services to the extracted audio signal Sₐ′ according to the determined level of service. The data processor 112 may contain a list of allowed levels of service and the corresponding services thereof. After receiving the level of service LoS from the tone identification circuit 110, the data processor 112 can determines the services based on the received parameter LoS, and perform the determined services to the extracted audio signal Sa′. The services provided to the extracted audio signal Sₐ′ may include audio phase correction, amplitude correction, arithmetic calculation, noise suppression, different frequency bands filtering or simply passes the present data without any processing. After the extracted audio signal Sₐ′ is processed, the signal processing method 9 is completed and exited (S920).

Although the set of tones only includes the information on the level of service LoS, in some embodiments, the manufacturer identifier MID is also encoded into the set of tones, the tone identification circuit 110 can further determine the manufacturer identifier MID according to the extracted set of tones Sₜ′ (S914), and the data processor 112 can search from a list of eligible manufacturers for the manufacturer identifier MID, and when a matched manufacturer is found, perform the services for the extracted audio signal Sₐ′ based on the level of service LoS (S918). When the manufacturer identifier MID is not found in the eligible manufacturers, the data processor 112 will simply play or record the extracted audio signal Sₐ′ without further data processing.

The signal processing method 9 provides appropriate level of the service to each user by including the information of the manufacturer identifier and the level of service indicator into the audio signal, enhancing service management to the microphone system.

As used herein, the term “determining” encompasses calculating, computing, processing, deriving, investigating, looking up (e.g., looking up in a table, a database or another data structure), ascertaining and the like. Also, “determining” may include resolving, selecting, choosing, establishing and the like.

The various illustrative logical blocks, modules and circuits described in connection with the present disclosure may be implemented or performed with a general-purpose processor, a digital signal processor (DSP), an application-specific integrated circuit (ASIC), a field programmable gate array signal (FPGA) or other programmable logic device, discrete gate or transistor logic, discrete hardware components or any combination thereof designed to perform the functions described herein. A general purpose processor may be a microprocessor, but in the alternative, the processor may be any commercially available processor, controller, microcontroller or state machine.

The operations and functions of the various logical blocks, units, modules, circuits and systems described herein may be implemented by way of, but not limited to, hardware, firmware, software, software in execution, and combinations thereof.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method adopted by an audio apparatus, comprising:
generating an audio signal;
generating a set of tones which represents a level of service;
modulating the audio signal with the set of tone to generate a modulated signal; and
amplifying the modulated signal;
wherein the level of service indicates a service provided to the audio signal.

2. The method of claim 1, further comprising:
transforming the amplified signal to a frequency domain signal;
extracting the set of tones from the frequency domain signal;
determining the level of service based on the extracted set of tones;
extracting the audio signal from the frequency domain signal; and
performing a service to the extracted audio signal according to the determined level of service.

3. The method of claim 1, wherein the set of tones further represents a manufacturer identifier;
the method further comprises determining the manufacturer identifier based on the extracted set of tones; and
the performing step comprises performing the service to the extracted audio signal when the manufacturer identifier matches to an entry in an authorized list.

4. The method of claim 3, wherein the set of tones is programmable to represent a combination of the level of service and the manufacturer identifier.

5. The method of claim 1, wherein the set of tones have amplitudes less than that of the audio signal.

6. The method of claim 1, wherein the set of tones comprises a fixed number of tones at fixed frequencies.

7. The method of claim 1, wherein each two adjacent tones in the set of tones comprises a programmable frequency ratio.

8. The method of claim 1, wherein each two adjacent tones in the set of tones comprises a programmable amplitude ratio.

9. The method of claim 1, wherein the set of tones comprises a programmable number of tones.

10. The method of claim 1, wherein the modulating step is performed in a known timing.

11. The method of claim 1, wherein the modulating step is performed periodically.

12. An audio apparatus, comprising:
a microphone, configured to generate an audio signal;
a tone generator, configured to generate a set of tones which represents a level of service, wherein the level of service indicates a service provided to the audio signal;
a modulator, coupled to the microphone and the tone generator, configured to modulate the audio signal with the set of tone to generate a modulated signal; and
an amplifier, coupled to the modulator, configured to amplifying the modulated signal.

13. The audio apparatus of claim 12, further comprising:
a frequency domain transformer, coupled to the amplifier, configured to transform the amplified signal to a frequency domain signal, and extract the set of tones and the audio signal from the frequency domain signal
a tone identification circuit, coupled to the frequency domain transformer, configured to determine the level of service based on the extracted set of tones; and
a data processor, coupled to the tone identification circuit, configured to perform a service to the extracted audio signal according to the determined level of service.

14. The audio apparatus of claim 12, wherein the set of tones further represents a manufacturer identifier;
the tone identification circuit is configured to further determine the manufacturer identifier based on the extracted set of tones; and
the data processor is configured perform the service to the extracted audio signal when the manufacturer identifier matches to an entry in an authorized list.

15. The audio apparatus of claim 14, wherein the set of tones is programmable to represent a combination of the level of service and the manufacturer identifier.

16. The audio apparatus of claim 12, wherein the set of tones have amplitudes less than that of the audio signal.

17. The audio apparatus of claim 12, wherein the set of tones comprises a fixed number of tones at fixed frequencies.

18. The audio apparatus of claim 12, wherein each two adjacent tones in the set of tones comprises a programmable frequency ratio.

19. The audio apparatus of claim 12, wherein each two adjacent tones in the set of tones comprises a programmable amplitude ratio.

20. The audio apparatus of claim 12, wherein the set of tones comprises a

21. The audio apparatus of claim 12, wherein the modulator step is configured to modulate the audio signal with the set of tone to generate a modulated signal in a known timing.

22. The audio apparatus of claim 12, wherein the modulator step is configured to modulate the audio signal with the set of tone to generate a modulated signal periodically.
